(19) United States
(12) Patent Application Publication
(10) Pub. No.: US 2007/0188308 A1
(43) Pub. Date: Aug. 16, 2007

(54) Vehicular indicator audio controlling

(76) Inventor: Bruce Scott Lavoie, Cambridge, MA (US)

Correspondence Address: FISH & RICHARDSON PC, P.O. BOX 1022, MINNEAPOLIS, MN, 55440-1022, US

(21) Appl. No.: 11/353,646

(22) Filed: Feb. 14, 2006

(51) Int. Cl. B60Q 1/00; H03G 3/20

(52) U.S. Cl. 340/425.5; 381/57

(57) ABSTRACT

A vehicle audio system including an assessor to assess the acoustic energy impacting the operator of the vehicle, and indicator audio signal source and an indicator audio controller to determine modifications to the indicator audio signal with respect to the assessment of the acoustic energy.

### BACKGROUND

This specification describes methods and apparatus for controlling auditory indicators associated with events in vehicles.

### SUMMARY

In one aspect of the invention, a method for processing indicator audio signals in a vehicle cabin includes assessing the acoustic energy present in the vehicle cabin to provide an acoustic energy assessment; generating an indicator audio signal; responsive to the acoustic energy assessment, modifying the indicator audio signal; and transducing the modified indicator audio signal into indicator audio audible to the vehicle operator. The assessing may include measuring the acoustic energy. The measuring may be done with a microphone. The assessing may include altering the assessment to reduce the effect of the indicator audio. The altering may include filtering the output of the microphone. The assessing may include monitoring audio signals generated by an entertainment system. The assessing may include estimating the acoustic energy expected to be present based on a measurable vehicle condition. The condition may include at least one of road speed, engine speed, transmission gear, road surface quality, tire pressure, window position, convertible roof position, windshield wiper speed, climate control settings, and ventilation fan speed. The assessing the acoustic energy may include estimating the acoustic energy expected to be present using at least one of a group of parameters consisting of the size of the vehicle cabin; the shape of the vehicle cabin; the passenger capacity of the vehicle cabin; and whether an occupant of the vehicle cabin is wearing a helmet. The generating an indicator audio signal may be in response to at least one of a group of conditions consisting of a turn signal is active; a seat belt is not fastened; headlights are on; a door is ajar; radar radiation detected; fuel is low; engine temperature is outside the proper range; tire pressure is outside the proper range; a curb or obstruction is near; a vehicle warning light is activated; and vehicle is out of lane. The generating the indicator audio signal may be performed by a navigation system. The generating the indicator audio signal may be performed by a remote communication device. The generating the indicator audio signal is performed by a hands-free telephone. The modifying the indicator audio signal may include amplifying. The modifying the indicator audio signal may include compressing the dynamic range. The vehicle may be a motorcycle.

In another aspect of the invention, an apparatus for processing indicator audio signals in a vehicle includes an assessor to provide an assessment of the acoustic energy present in a vehicle cabin; an indicator audio signal source; and an indicator audio controller coupled to the assessor to determine, responsive to the assessment, modifications of an indicator audio signal. The apparatus for processing indicator audio signals may further include a signal modifier to modify the indicator audio signal responsive to the assessor. The signal modifier may include an audio amplifier. The signal modifier may include a compressor. The apparatus may further include a transducer to convert a modified indicator audio signal into acoustic energy audible to a vehicle operator. The transducer may be located inside a helmet constructed and arranged to be worn by a vehicle operator. The assessor may include a microphone. The assessor may be communicatingly coupled to the indicator audio signal source. The apparatus may further include a filter to modify the output of the microphone. The filter may be a low-pass filter. The filter may be a smoothing filter. The vehicle may include an entertainment system and the assessor may be constructed and arranged to receive a measurement of the amplitude of the signal being transmitted from the entertainment system to a transducer. The vehicle may further include apparatus for determining at least one of road speed, engine speed, transmission gear, road surface quality, tire pressure, window position, convertible roof position, windshield wiper speed, climate control settings, and ventilation fan speed. The assessor may include a processor and a memory. The memory may contains data including a conversion table of sensor types and conversion algorithms. The processor may be constructed and arranged to execute the algorithm associated with the sensor in the conversion table. The assessor may include a smoothing filter. The smoothing filter may be a low-pass filter. The smoothing filter may be constructed and arranged to be reconfigured dynamically. The indicator audio signals may be generated in response to at least one of a turn signal is active; a seat belt is not fastened; headlights are on; a door is ajar; radar radiation detected; fuel is low; engine temperature is outside the proper range; tire pressure is outside the proper range; or a curb or obstruction is near; and vehicle is out of lane. The indicator audio signal source may be external to the apparatus. The indicator audio signal source may be a navigation system. The indicator audio signal source may be a remote communication device. The indicator audio signal source may be a hands-free telephone. The vehicle is a motorcycle.

Other features, objects, and advantages will become apparent from the following detailed description, when read in connection with the following drawing, in which:

### BRIEF DESCRIPTION OF THE DRAWING

FIG. 1 shows a block diagram of one embodiment of the system;

FIG. 2 shows a block diagram of one alternative embodiment of the system; and

FIGS. 3A-3D are flow charts showing a process for operating the systems of FIGS. 1 and 2.

### DETAILED DESCRIPTION

The disclosed methods and devices control vehicular indicator audio. Vehicle operators are presented with auditory indicators representing events and information in such a manner as to be discernible and intelligible over the existing acoustic energy present about the vehicle operator's ears. A system according to the specification determines the acoustic energy, either through direct measurement, prediction, or a combination of both, and adjusts playback of the auditory indicators such that the indicators remain audible to vehicle occupants under varying conditions. The acoustic energy present may be determined at one or more passenger positions. Typically, it is more important that the auditory indicator be audible at the driver position than at other positions. The determination of acoustic energy may be done exclusively at that position or, if the determination is made at more than one position, the driver position may be weighted more heavily than other positions.

Typical events and information include turn signal activated, navigational instructions, low fuel warning, radar radiation detected, etc.; they are herein collectively referred to as indicators and the associated acoustic energy is referred to as indicator audio. Indicator audio is generated by transducing an indicator audio signal (stored in either analog or digital form) into indicator audio by one or more transducers. The indicator audio may be generated in response to some event, such as a door being opened or a headlight being illuminated, or they may be generated for some other reason, for example, as navigation instructions. The process of converting an indicator audio signal into indicator audio is herein referred to as playing an indicator. Playing an indicator may also include generation of the indicator audio signal. The acoustic energy present about the vehicle operator's ears may originate from outside the vehicle, inside the vehicle, entertainment systems, passengers, or the vehicle itself. While the vehicle operator may not consider all aspects of this acoustic energy to be noise, acoustic energy about the vehicle operator's ears is referred to herein as cabin noise. The term cabin noise does not, however, include the indicator audio itself.

It is important for occupants, particularly the driver, to hear the indicator audio above the cabin noise, desirably without being annoyingly loud when there is little cabin noise. A vehicle indicator audio controlling system as described in this specification acts to ensure that indicator audio remains audible. In general, this is done by ensuring that indicator audio is reproduced at a level at least as large as, if not higher than, the level of cabin noise present in the vehicle, and at a level that is sufficiently loud as to be clearly audible by a vehicle occupant. Indicator audio can be reproduced at a first fixed level as long as cabin noise level remains below a threshold level. Once the cabin noise level gets above the threshold level, the level of the indicator audio is modified by the signal modifier to maintain the indicator audio energy at a certain level relative to the cabin noise level. For example, indicator audio may be reproduced at an averaged SPL level that is at least +6 dB SPL relative to the level of cabin noise present (other systems can maintain a different ratio, such as +3 Db SPL, or 0 Db SPL, and may compare unweighted SPL, weighted SPL measures (such as A, B, or C) or any of a variety of other measures.

Though the elements of several views of the drawing may be shown and described as discrete elements in a block diagram, unless otherwise indicated, the elements may be implemented as one of, or a combination of, analog circuitry, digital circuitry, or one or more microprocessors executing software instructions. Software instructions may include digital signal processing (DSP) instructions. Unless otherwise indicated, signal lines may be implemented as discrete analog or digital signal lines, as a single discrete digital signal line with appropriate signal processing to process separate streams of audio signals, or as elements of a wireless communication system. Some of the processing operations are expressed in terms of the calculation and application of coefficients. The equivalent of calculating and applying coefficients can be performed by other signal processing techniques and are included within the scope of this specification. Unless otherwise indicated, audio signals may be encoded in either digital or analog form.

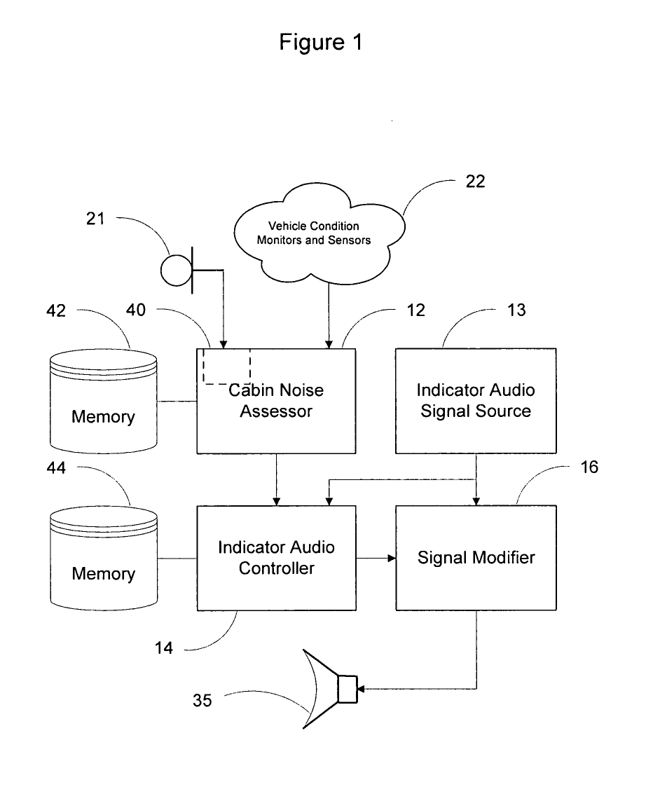

FIG. 1 shows a block diagram of a system implementing the methods disclosed. A vehicle (not shown) is equipped with one or more microphones 21, various sensors 22, a cabin noise assessor 12, an indicator audio signal source 13, an indicator audio controller 14, a signal modifier 16, cabin noise assessor memory 42, indicator audio controller memory 44, and one or more transducers 35. These elements may be separate or combined in any manner; for example, the indicator audio controller may be a part of the signal modifier.

Cabin noise assessor 12 may have an associated cabin noise assessor memory 42 which may store fixed information about the vehicle's characteristics (for example the size of the cabin, the number of seats, etc.), and stores cabin noise assessor configuration data (for example, the number and location of noise measurement microphones), and any necessary cabin noise assessment software. Indicator audio controller 14 has an associated indicator audio controller memory 44 which stores indicator audio controller configuration data and any necessary indicator audio controller software. Cabin noise assessor memory 42 and indicator audio controller memory 44 may be implemented using distinct or non-distinct hardware. The memory hardware may be any kind of memory capable of storing the requisite data; the memory hardware used for the cabin noise assessor memory 42 should be capable of storing noise assessment measurements. Signal modifier 16 could be an audio amplifier, a pre-amplifier, a filter, an equalizer, or some other type of audio signal processing device. One or more transducers 35 may be the same transducers used by an entertainment system in the vehicle.

The one or more microphones 21, or various sensors 22, or both, transmit data to cabin noise assessor 12. Cabin noise assessor 12 provides an assessment of cabin noise to indicator audio controller 14. When there is indicator audio to be played indicator audio signal source 13 provides an indicator audio signal to indicator audio controller 14. When there is indicator audio to be played, indicator audio controller 14 determines an appropriate modification which is used by signal modifier 16 to modify the indicator audio signal coming from indicator audio signal source 13. The signal modifier 16 then provides the modified indicator audio signal to one or more transducers 35 which convert the signal into indicator audio.

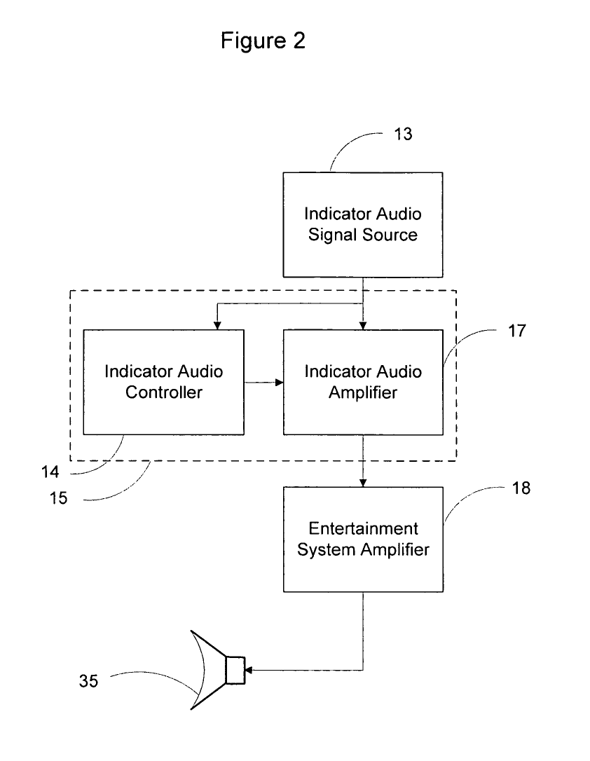

FIG. 2 shows a block diagram of an alternative system implementing the methods disclosed. As in FIG. 1, there is an indicator audio signal source 13, an indicator audio controller 14, and one or more transducers 35. The modifier 16, from FIG. 1, however, can be replaced by an indicator audio amplifier 17 and an entertainment system amplifier 18. This allows the system to use an existing external entertainment system amplifier to assist in amplifying the indicator audio signal. The indicator audio amplifier 17 and the indicator audio controller 14 may be grouped as one element 15.

In order to provide the vehicle operator with indicator audio discernable and intelligible over the cabin noise, the system assesses the cabin noise and then modifies the indicator audio signal to compensate. Cabin noise can be assessed by direct measurement, by estimation based on vehicle conditions, or by a combination of direct measurement and estimation. Direct measurements can be made via one or more microphones placed inside the cabin. Various signal processing operations can be applied to the output of a microphone to provide a signal representative of vehicle cabin noise that is useful for determining how to modify indicator audio so that it remains audible. A level detection circuit may be used to detect a level of cabin noise present, by detecting the level of the microphone signal. The detector may detect peak, average, RMS, or other levels associated with the cabin noise signal. The detectors may further include signal processing for modifying the detected level signal as a function of time. The detected level signal may be smoothed as a function of time, or filtered as desired. There are many known techniques for constructing level detectors for audio signals. The detectors may be constructed to react in a desired manner to rapid changes in the cabin noise present. For example, it may be desirable to ignore very rapid increases in cabin noise level, and only detect increases that occur over a longer time period. An attack time constant of the detector can be constructed to accomplish this. For example, an attack time constant for a detector may be 10-20 msec. An increase in cabin noise that occurs over time period shorter than 10-20 msec then will not substantially affect the detected level. A decay time constant may also be constructed to maintain the detected level signal value for a period of time after the cabin noise present has dropped in level. It may be desirable for the detected level to decay slowly following a decrease in cabin noise. For example, a decay time constant of 5 seconds may be used. Having a shorter attack time constant and a longer decay time constant provides an improved detected signal for use by the indicator audio controller. Alternatively, an attack time constant that is longer than the typical length of an indicator audio signal can be used, to reduce the sensitivity of the detected signal level to the presence or absence of the indicator audio. For example, an attack time constant of 5 seconds could be used, and a longer decay time constant of 20 seconds could be used.

Other signal processing may be applied to generate a useful signal representative of vehicle cabin noise. For example, a filter may be used to process direct measurements. The filter may be designed to attenuate spectral energy in the frequency range where indicator audio signals have substantial energy. For example, a low pass filter with a cutoff frequency chosen so that energy in the frequency range where indicator audio signals have substantial spectral energy are attenuated. The filtered signal can then be level detected, as described above. By excluding energy in the frequency range where indicator audio signals have substantial spectral energy, the filtered output (and the level detected filtered output) will show little sensitivity to the presence or absence of indicator audio signals. It is desirable for the signal used to represent the level of cabin noise present to have low sensitivity to the presence or absence of indicator audio signals present, to avoid an unstable condition.

Other processing may be used to estimate the perceived loudness of the cabin noise. For example, a weighted SPL measurement can be made using the microphone output signal. Various weightings can be used such as A, B, C, or any other measure. More sophisticated models of human perception may also be used to estimate loudness, such as that described by ANSI standard S3.4-2005, or in Moore & Glasberg (1997)“A Model for the Prediction of Thresholds, Loudness and Partial Loudness”, J. Audio. Eng. Soc. 45 224-240. The loudness of indicator audio signals reproduced at various levels can be determined, and then compared to the estimated loudness of the cabin noise for use by the indicator audio controller to modify the indicator audio signal to maintain its loudness at a level relative to the loudness of cabin noise.

Another signal processing approach that can be used to avoid the unstable condition mentioned earlier is to freeze the value of the signal representative of cabin noise during times where indicator audio is being played, so that the representative cabin noise signal does not change during this time period. Since indicator audio signals are generated by systems within the vehicle, their presence or absence can easily be detected by monitoring the indicator audio signal source 13 output, by monitoring a separate control line, or by any other appropriate means.

A signal representative of the cabin noise present in the vehicle cabin can also be obtained by estimating the noise, rather than directly measuring the noise with a microphone. Estimation can be used to provide an assessment of cabin noise in the presence of complications like excessive vehicle vibration and wind.

Estimation of cabin noise based on vehicle conditions can be done with circuitry or with a computer running software. The estimation of cabin noise can be premised on a variety of vehicle conditions including current transmission gear, road speed, window positions, entertainment system volume settings, climate control settings, and road conditions. Measuring these conditions may require additional sensors, or the measuring may use sensors already incorporated within the vehicle, or information available on a vehicle communication bus, that may be used for other purposes. The estimation may be done by operating the car under various operating conditions, and noise measurements taken for the various conditions. The estimation may also include modeling according to known techniques, for example, taking into account parameters such as the vehicle's size, shape, and passenger capacity. Algorithms for assessment of cabin noise may be tuned to account for the unique characteristics of specific vehicles. The estimated or modeled data then may be fit into an algorithm or look up table, using known techniques, to guide the setting of indicator audio compensation. The various sensors and noise generating devices may convey data to the cabin noise assessor via the vehicle data bus. Acoustic energy generated by entertainment systems can also be determined directly from the signals received by the entertainment system's transducers, using the system transfer function from transducer input to SPL output at a desired location, such as the driver's seat.

Cabin noise measured by microphone may include measurement of indicator audio, which is undesirable. As indicator audio is generally radiated for a short time, to avoid feedback, the noise assessment may be designed to explicitly exclude microphone measurements during intervals while indicator audio is radiates. The presence of indicator audio can be determined by detecting if a signal is present at the output of the indicator audio signal source, by a separate control line, or by any other appropriate means.

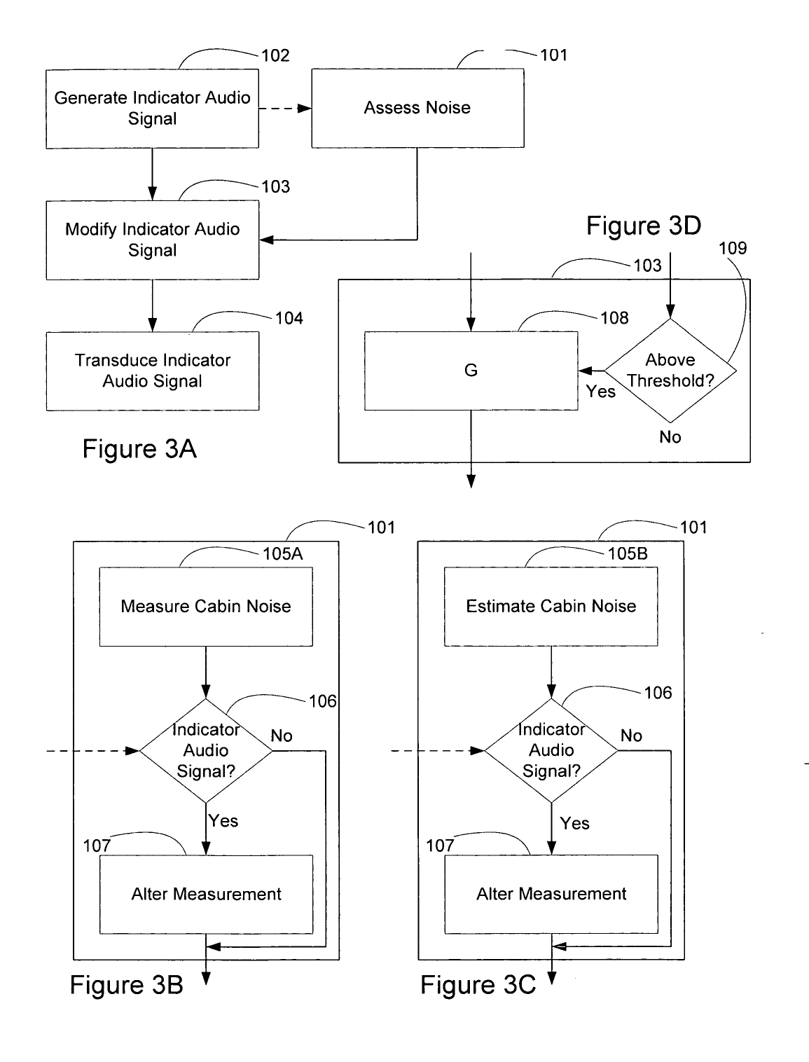

FIGS. 3A-3D are flow charts showing a process for using the system of FIGS. 1 and 2. Referring to FIG. 3A, at sub-process 101, cabin noise is continually assessed. In sub-process 102 an indicator audio signal is generated responsive to some event, such as a turn signal being activated. The generation of an indicator audio signal may be indicated to noise assessment sub-process 101. At sub-process 103, the audio signal is modified, for example by amplifying or compressing, in a manner responsive to sub-process 101. At sub-process 104, the modified indicator audio signal is transduced to indicator audio

Referring to FIG. 3B, there is shown an implementation of the noise assessment sub-process 101 in more detail. At sub-process 105A, cabin noise is measured, for example by a microphone 21 (of FIG. 1) and other associated circuitry. At sub-process 106, it is determined if an indicator audio signal is present in the system. If there is an indicator audio signal present, the cabin noise measurement is altered at sub-process 107 to lessen or eliminate indicator audio from the noise measurement. Alternatively, at sub-process 107, the cabin noise measurement can be altered by “freezing” the cabin noise measurement until there is no indicator audio signal present. In another alternative, the cabin noise measurement can compensate for the presence of indicator audio by configuring an optional filter 40, as shown in FIG. 1, to process microphone measurements. For example, use of a low-pass filter with a corner frequency below the frequency range of the indicator audio frequency spectrum effectively eliminates the indicator audio from the measurement. Other types of smoothing filters, such as windowed averaging filters can also be used. Alternatively, an adaptive filter configured in a noise cancellation mode could be dynamically tuned to filter out indicator audio signals from the microphone signal. In this configuration, the indicator audio signal source 13 output is used as a reference input to the adaptive filter. The output of the filter is subtracted from the microphone signal. The coefficients of the filter are adjusted so that the indicator audio signal portion of the microphone signal is canceled, leaving primarily the cabin noise. There are many techniques for performing the adjustment of the coefficients of the filters, for example as described in U.S. patent application Ser. No. 11/142,749.

Following sub-process 107, or following sub-process 106 if no indicator audio signal is present, the process proceeds to sub-process 103 of FIG. 3A.

FIG. 3C is identical to FIG. 3B, except the noise measurement sub-process 105A is replaced by a noise estimation sub-process 105B, and at sub-process 107 the estimate is altered. The noise estimation can be done as described above.

FIG. 3D shows an implementation of the modifying sub-process 103 in more detail. The modifying may include applying at sub-process 108 a gain G to the indicator audio signal. Gain G is sufficient to amplify the signal so that it is audible but not annoyingly loud under normal noise conditions. At step 109, it is determined if the noise assessment is above a threshold level. If the noise assessment is above the threshold level, the gain G may be increased (or other modification, such as compressing may be applied) so that the indicator audio is audible. In other implementations, at sub-process 108 there may be other forms of signal modification, such as compressing, applied to the indicator audio signal. Compressing the dynamic range can change the perceived loudness of the indicator audio and can therefore be used, either alone, or in combination with increasing the level of the indicator audio, to increase the perceived audibility of the indicator audio under changing cabin noise conditions. A maximum gain may also be imposed to protect the transducers as well as the hearing of the vehicle operator and any other vehicle passengers.

If the noise assessment is not above the threshold level, no change to sub-process 108 is applied.

These methods and devices can also be used with vehicle operators wearing a helmet, for example if the vehicle were a motorcycle. In this case, the system would need to be tuned with regard to the location of the transducers, which may be inside the helmet, and the effect of the helmet on noise. One or more microphones may be placed inside the helmet and additional sensors may be used to indicate the position of a face shield on the helmet. Thus minor modifications can be made to provide discernible and intelligible indicator audio to operators of other vehicle types. In a helmet implementation, the inside of the helmet, adjacent the user's ears may correspond to the vehicle “cabin” of other implementations

Numerous uses of and departures from the specific apparatus and techniques disclosed herein may be made without departing from the inventive concepts. Consequently, the invention is to be construed as embracing each and every novel feature and novel combination of features disclosed herein and limited only by the spirit and scope of the appended claims.

What is claimed is:

1. A method for processing indicator audio signals in a vehicle cabin comprising
assessing the acoustic energy present in the vehicle cabin to provide an acoustic energy assessment;
generating an indicator audio signal;
responsive to the acoustic energy assessment, modifying the indicator audio signal; and;
transducing the modified indicator audio signal into indicator audio audible to the vehicle operator.

2. A method for processing indicator audio signals according to claim 1, wherein the assessing comprises measuring the acoustic energy.

3. A method for processing indicator audio signals according to claim 2, wherein the measuring the acoustic energy comprises measuring the acoustic energy using a microphone.

4. A method for processing indicator audio signals according to claim 3, wherein the assessing comprises altering the assessment to reduce the effect of the indicator audio.

5. A method for processing indicator audio signals according to claim 3, wherein altering the assessment comprises filtering the output of the microphone.

6. A method for processing indicator audio signals according to claim 1, wherein the assessing comprises monitoring audio signals generated by an entertainment system.

7. A method for processing indicator audio signals according to claim 1, wherein the assessing comprises estimating the acoustic energy expected to be present based on a measurable vehicle condition.

8. A method for processing indicator audio signals according to claim 7, wherein the measurable vehicle condition comprises at least one condition selected from a group consisting of
road speed,
engine speed,
transmission gear,
road surface quality,
tire pressure,
window position,
convertible roof position,
windshield wiper speed,
climate control settings, and
ventilation fan speed.

9. A method for processing indicator audio signals according to claim 1, wherein the assessing the acoustic energy includes estimating the acoustic energy expected to be present using at least one of a group of parameters consisting of the size of the vehicle cabin; the shape of the vehicle cabin; the passenger capacity of the vehicle cabin; and whether an occupant of the vehicle cabin is wearing a helmet.

10. A method for processing indicator audio signals according to claim 1, wherein the generating an indicator audio signal is in response to at least one of a group of conditions consisting of
a turn signal is active;
a seat belt is not fastened;
headlights are on;
a door is ajar;
radar radiation detected;
fuel is low;
engine temperature is outside the proper range;
tire pressure is outside the proper range;
a curb or obstruction is near;
a vehicle warning light is activated; and
vehicle is out of lane.

11. A method for processing indicator audio signals according to claim 1, wherein the generating the indicator audio signal is performed by a navigation system.

12. A method for processing indicator audio signals according to claim 1, wherein the generating the indicator audio signal is performed by a remote communication device.

13. A method for processing indicator audio signals according to claim 1, wherein generating the indicator audio signal is performed by a hands-free telephone.

14. A method for processing indicator audio signals according to claim 1, wherein the modifying the indicator audio signal includes amplifying.

15. A method for processing indicator audio signals according to claim 1, wherein the modifying the indicator audio signal includes compressing the dynamic range.

16. A method for processing indicator audio signals according to claim 1, wherein the vehicle is a motorcycle.

17. An apparatus for processing indicator audio signals in a vehicle comprising
an assessor to provide an assessment of the acoustic energy present in a vehicle cabin;
an indicator audio signal source; and
an indicator audio controller coupled to the assessor to determine, responsive to the assessment, modifications of an indicator audio signal.

18. An apparatus for processing indicator audio signals according to claim 17, further comprising a signal modifier to modify the indicator audio signal responsive to the assessor.

19. An apparatus for processing indicator audio signals according to claim 18, wherein the signal modifier comprises an audio amplifier.

20. An apparatus for processing indicator audio signals according to claim 18, wherein the signal modifier comprises a compressor.

21. An apparatus for processing indicator audio signals according to claim 18, further comprising a transducer to convert a modified indicator audio signal into acoustic energy audible to a vehicle operator.

22. An apparatus for processing indicator audio signals according to claim 21, wherein the transducer is located inside a helmet constructed and arranged to be worn by a vehicle operator.

23. An apparatus for processing indicator audio signals according to claim 17, wherein the assessor comprises a microphone.

24. An apparatus for processing indicator audio signals according to claim 17, wherein the assessor is communicatingly coupled to the indicator audio signal source.

25. An apparatus for processing indicator audio signals according to claim 23, further comprising a filter to modify the output of the microphone.

26. An apparatus for processing indicator audio signals according to claim 25, wherein the filter is a low-pass filter.

27. An apparatus for processing indicator audio signals according to claim 25, wherein the filter is a smoothing filter.

28. An apparatus for processing indicator audio signals according to claim 17, wherein the vehicle includes an entertainment system and the assessor is constructed and arranged to receive a measurement of the amplitude of the signal being transmitted from the entertainment system to a transducer.

29. An apparatus for processing indicator audio signals to claim 17, wherein the vehicle further comprises apparatus for determining at least one of
road speed,
engine speed,
transmission gear,
road surface quality,
tire pressure,
window position,
convertible roof position,
windshield wiper speed,
climate control settings, and
ventilation fan speed.

30. An apparatus for processing indicator audio signals according to claim 29, wherein
the assessor comprises a processor and a memory;
the memory contains data including a conversion table of sensor types and conversion algorithms; and
the processor is constructed and arranged to execute the algorithm associated with the sensor in the conversion table.

31. An apparatus for processing indicator audio signals according to claim 17, wherein the assessor includes a smoothing filter.

32. An apparatus for processing indicator audio signals according to claim 31, wherein the smoothing filter is a low-pass filter.

33. An apparatus for processing indicator audio signals according to claim 31, wherein the smoothing filter is constructed and arranged to be reconfigured dynamically.

34. An apparatus for processing indicator audio signals according to claim 17, wherein the indicator audio signals are generated in response to at least one of
a turn signal is active;
a seat belt is not fastened;
headlights are on;
a door is ajar;
radar radiation detected;
fuel is low;
engine temperature is outside the proper range;
tire pressure is outside the proper range;
a curb or obstruction is near; and
vehicle is out of lane.

35. An apparatus for processing indicator audio signals according to claim 17, wherein the indicator audio signal source is external to the apparatus.

36. An apparatus for processing indicator audio signals according to claim 35, wherein the indicator audio signal source is a navigation system.

37. An apparatus for processing indicator audio signals according to claim 35, wherein the indicator audio signal source is a remote communication device.

38. An apparatus for processing indicator audio signals according to claim 35, wherein the indicator audio signal source is a hands-free telephone.

39. An apparatus for processing indicator audio signals according to claim 17, wherein the vehicle is a motorcycle.
